(19) United States
(12) Patent Application Publication
(10) Pub. No.: US 2023/0043402 A1
(43) Pub. Date: Feb. 9, 2023

(54) TRENCH-TYPE MESFET

(71) Applicant: Novel Crystal Technology, Inc., Saitama (JP)

(72) Inventor: Kohei SASAKI, Saitama (JP)

(73) Assignee: Novel Crystal Technology, Inc., Saitama (JP)

(21) Appl. No.: 17/788,861

(22) PCT Filed: Dec. 15, 2020
(86) PCT No.: PCT/JP2020/046717

§ 371 Date: Jun. 24, 2022

(30) Foreign Application Priority Data
Dec. 25, 2019 (JP) 2019-234981

(51) Int. Cl. H01L 29/812; H01L 29/24; H01L 29/423; H01L 29/47

(52) U.S. Cl. CPC H01L 29/8122; H01L 29/24; H01L 29/47; H01L 29/42316

(57) ABSTRACT

A trench-type MESFET includes an n-type semiconductor layer including a Ga₂O₃-based single crystal and including plural trenches opening on one surface, first insulators respectively buried in bottom portions of the plural trenches, gate electrodes respectively buried in the plural trenches so as to be placed on the first insulators and so that side surfaces thereof are in contact with the n-type semiconductor layer, a source electrode connected to a mesa-shaped portion between the adjacent trenches of the n-type semiconductor layer, second insulators respectively buried in the plural trenches so as to be placed on the gate electrodes to insulate the gate electrodes and the source electrode, and a drain electrode directly or indirectly connected to the n-type semiconductor layer on a side opposite to the source electrode.

### TECHNICAL FIELD

The present invention relates to a trench-type MESFET.

### BACKGROUND ART

Ga₂O₃-based trench MOSFETs with a gate electrode buried in a semiconductor layer are known (see, e.g., Patent Literature 1). A trench MOSFET has high withstand voltage characteristics due to the trench gate-structure thereof.

In MOSFETs, resistance of the semiconductor layer and withstand voltage characteristics are generally correlated. Increasing resistance of the semiconductor layer can improve withstand voltage characteristics but causes an increase in conduction losses. Compared to planar MOSFETs, trench MOSFETs can easily achieve both high withstand voltage and low loss since the trench gate-structure thereof improves withstand voltage characteristics without increasing resistance of the semiconductor layer.

### Citation List

### Patent Literatures

Patent Literature 1: JP 2016/15503 A

### SUMMARY OF INVENTION

### Technical Problem

However, the trench MOSFET disclosed in Patent Literature 1 cannot operate at very high frequencies and cannot be used for applications that require to operate at high frequencies, such as applications in cell phone base station equipment or wireless power feeding equipment.

It is an object of the invention to provide a trench-type MESFET that can be driven at high frequency while having a high withstand voltage.

### Solution to Problem

To achieve the above object, one aspect of the invention provides a trench-type MESFET defined by (1) to (5) below.
(1) A trench-type MESFET, comprising:
   an n-type semiconductor layer comprising a Ga₂O₃-based single crystal and comprising a plurality of trenches opening on one surface;
   first insulators respectively buried in bottom portions of the plurality of trenches;
   gate electrodes respectively buried in the plurality of trenches so as to be placed on the first insulators and so that side surfaces thereof are in contact with the n-type semiconductor layer;
   a source electrode connected to a mesa-shaped portion between the adjacent trenches of the n-type semiconductor layer;
   second insulators respectively buried in the plurality of trenches so as to be placed on the gate electrodes to insulate the gate electrodes and the source electrode; and
   a drain electrode directly or indirectly connected to the n-type semiconductor layer on a side opposite to the source electrode.
(2) The trench-type MESFET defined by (1), wherein the gate electrode comprises NiO.
(3) The trench-type MESFET defined by (1) or (2), wherein a curvature radius at an apex of a curve at an edge of a bottom portion of the gate electrode in a cross section in a width direction of the trench is not less than 0.1 µm.
(4) The trench-type MESFET defined by any one of (1) to (3), wherein a donor concentration in a region of the n-type semiconductor layer between a bottom of the trench and a bottom surface of the n-type semiconductor layer is not more than 7×10¹⁶cm⁻³.
(5) The trench-type MESFET defined by any one of (1) to (4), wherein a thickness of the first insulator is in a range of not less than 50 nm and not more than 300 nm. Advantageous Effects of Invention

According to the invention, it is possible to provide a trench-type MESFET that can be driven at high frequency while having a high withstand voltage.

### BRIEF DESCRIPTION OF DRAWINGS

FIG. 1 is a vertical cross-sectional view showing a trench-type MESFET in the first embodiment.

FIG. 2 is a partially enlarged view of FIG. 1, showing the vicinity of a bottom portion of a trench of the trench-type MESFET.

FIG. 3 is a graph showing a relationship between gate voltage and gate leakage current and a relationship between gate voltage and drain current for the trench-type MESFET in Example 1 when Pt is used as a material of a gate electrode and drain voltage of 1.2 kV is applied.

FIG. 4 is a vertical cross-sectional view showing a pn junction diode in Example 1.

FIG. 5 is a graph showing a relationship between applied voltage and current density for the pn junction diode in Example 1.

FIG. 6 is a graph showing a relationship between gate voltage and gate leakage current and a relationship between gate voltage and drain current for the trench-type MESFET in Example 1 when NiO is used as a material of a gate electrode 13 and drain voltage of 1.2 kV is applied.

FIG. 7 is a graph showing a relationship between drain voltage and drain current for the trench-type MESFET in Example 1 when NiO is used as the material of the gate electrode 13 and gate voltage of 0 to 1.6 V is applied.

FIG. 8 is a graph showing a relationship between a curvature radius of the gate electrode and electric field intensity at points in a channel layer and an insulator for the trench-type MESFET in Example 2.

FIG. 9 is a graph showing a relationship between a donor concentration in a withstand voltage layer and electric field intensity at points in the withstand voltage layer and the insulator for the trench-type MESFET in Example 3.

FIG. 10 is a graph showing a relationship between a thickness of the insulator and electric field intensity at points in the withstand voltage layer and the insulator for the trench-type MESFET in Example 4.

### DESCRIPTION OF EMBODIMENTS

### Embodiments

### Constitution of a Trench-Type MESFET

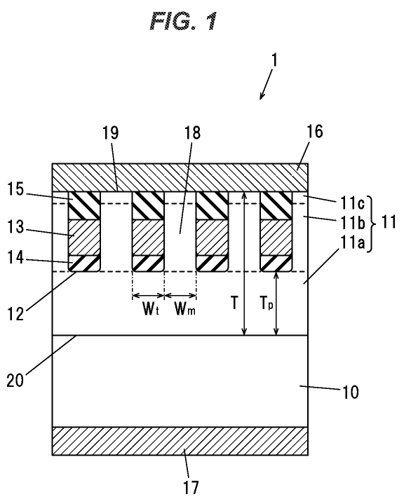

FIG. 1 is a vertical cross-sectional view showing a trench-type MESFET (Metal Semiconductor Field Effect Transistor) 1 in the first embodiment. The trench-type MESFET 1 is a vertical field-effect transistor having a trench-gate structure.

The trench-type MESFET 1 includes an n-type semiconductor substrate 10, an n-type semiconductor layer 11 that is a layer stacked on the n-type semiconductor substrate 10 and has plural trenches 12 opening on a surface 19 on the opposite side to the n-type semiconductor substrate 10, first insulators 14 respectively buried in bottom portions of the plural trenches 12, gate electrodes 13 respectively buried in the plural trenches 12 so as to be placed on the first insulators 14 and so that side surfaces thereof are in contact with the n-type semiconductor layer 11, a source electrode 16 connected to mesa-shaped portions 18 between adjacent trenches 12 of the n-type semiconductor layer 11, and a drain electrode 17 formed on a surface of the n-type semiconductor substrate 10 on the opposite side to the n-type semiconductor layer 11.

Depletion layers are formed in the mesa-shaped portions 18 of the n-type semiconductor layer 11 due to Schottky barriers formed at interfaces between the n-type semiconductor layer 11 and the gate electrodes 13. In the trench-type MESFET 1, it is possible to control a thickness of the depletion layer by gate voltage (voltage applied to the gate electrodes 13, or voltage applied between the source electrode and the gate electrodes 13 when the source electrode 16 is grounded), and thereby possible to open/close channels in the mesa-shaped portions 18.

The trench-type MESFET 1 may be either of a normally-off type or a normally-on type, but is usually manufactured to be of the normally-off type in view of safety when used as a power device. It is to prevent conduction between the source electrode 16 and the drain electrode 17 in the event that the gate becomes uncontrollable due to wire breakage, etc., in a gate circuit.

In the normally-off trench-type MESFET 1, the channels in the mesa-shaped portions 18 are closed by the depletion layers in a state in which gate voltage is not applied. Then, by applying a gate voltage of not less than the threshold voltage, the depletion layers become thin, the channels open, and current flows from the drain electrode 17 to the source electrode 16.

The n-type semiconductor substrate 10 is formed of an n-type Ga₂O₃-based single crystal containing a group IV element such as Si or Sn as a donor. A donor concentration in the n-type semiconductor substrate 10 is, e.g., not less than 1.0×10¹⁸cm⁻³ and not more than 1.0×10²⁰cm⁻³. A thickness of the n-type semiconductor substrate 10 is, e.g., not less than 10 µm and not more than 600 µm.

The Ga₂O₃-based single crystal here means a Ga₂O₃ single crystal or is a Ga₂O₃ single crystal doped with an element such as Al or In, and may be, e.g., a (GaₓAl_{y}In_{(1-x-y)})₂O₃ (0<x≤1, 0≤y<1, 0<x+y≤1) single crystal which is a Ga₂O₃ single crystal doped with Al and In. The band gap is widened by adding Al and is narrowed by adding In. The Ga₂O₃ single crystal mentioned above has, e.g., a β-crystal structure.

A plane orientation of the n-type semiconductor substrate 10 is not specifically limited, but is preferably a (001) plane on which a Ga₂O₃-based single crystal constituting the n-type semiconductor layer 11 is formed at a high growth rate, or it is also preferably a (011) plane on which a Ga₂O₃-based single crystal film with a flat surface can be grown.

The n-type semiconductor layer 11 is formed of an n-type Ga₂O₃-based single crystal containing a group IV element such as Si or Sn as a donor. A thickness T of the n-type semiconductor layer 11 is, e.g., not less than 1 µm and not more than 500 µm.

The n-type semiconductor layer 11 has a channel layer 11b in which the gate electrodes 13 are buried and channels are formed when gate voltage is applied, a withstand voltage layer 11a provided under the channel layer 11b to maintain withstand voltage, and a contact layer 11c formed in the vicinity of an interface with the source electrode 16 by ion implantation or epitaxial growth, etc., to provide an ohmic connection between the source electrode 16 and the n-type semiconductor layer 11.

Here, a region of the n-type semiconductor layer 11 located below (on the drain electrode 17 side of) the height of the bottoms of the trenches 12, i.e., a region between the bottoms of the trenches 12 and a bottom surface 20 (a surface on the drain electrode 17 side) of the n-type semiconductor layer 11 is the withstand voltage layer 11a and a thickness thereof is defined as Tₚ. A region of the n-type semiconductor layer 11 located above (on the source electrode 16 side of) the height of the bottoms of the trenches 12 is the channel layer 11b, and the contact layer 11c is provided in the vicinity of the upper end of the channel layer 11b.

A donor concentration in the withstand voltage layer 11a is one of the parameters determining the breakdown characteristics of the trench-type MESFET 1, and given that breakdown field strength of Ga₂O₃ stays constant at 8 MV/cm, it is preferably not more than about 3×10¹⁷ cm⁻³ to obtain withstand voltage of 600 V, not more than about 1.5×10¹⁷ cm⁻³ to obtain withstand voltage of 1200 V, not more than about 5.4×10¹⁶ cm⁻³ to obtain withstand voltage of 3300 V, not more than about 2.7×10¹⁶ cm⁻³ to obtain withstand voltage of 6600 V, not more than about 1.5×10¹⁶ cm⁻³ to obtain withstand voltage of 12000 V, and not more than about 2×10¹⁵ cm⁻³ to obtain withstand voltage of 100000 V. To obtain withstand voltage of less than 600 V or withstand voltage of more than 6600 V, the concentration is respectively set to appropriate values. In addition, when the maximum breakdown field strength of Ga₂O₃ is about 4 MV/cm, the concentrations are respectively not more than half of the above-mentioned values.

The thickness Tₚ of the withstand voltage layer 11a is one of parameters determining the breakdown characteristics of the trench-type MESFET 1, and given that breakdown field strength of Ga₂O₃ stays constant at 8 MV/cm which is a value estimated from the band gap, the thickness Tₚ needs to be, e.g., at least not less than about 1 to 2 µm to obtain performance of having withstand voltage of 600V used for home appliances or in-vehicle devices, etc., not less than about 3 µm to obtain withstand voltage of 1200 V used for industrial equipment, etc., not less than about 8 to 9 µm to obtain withstand voltage of 3300 V used for large transportation equipment such as bullet train, etc., not less than about 16 to 17 µm to obtain withstand voltage of 6600 V in high power applications such as power generation and transmission, etc., not less than about 30 µm to obtain withstand voltage of 12000 V in medium-voltage circuit breakers, and not less than about 250 µm to obtain withstand voltage of 100000 V in high-voltage circuit breakers.

The maximum breakdown field strength of Ga₂O₃ has not been able to be actually measured at the moment, and if it is about 4 MV/cm which is the largest of the actually measured values, the film thicknesses mentioned above need to be doubled. For example, about 500 µm is required to obtain withstand voltage of 100000 V. To obtain withstand voltage of less than 600 V for small home appliances, the thickness Tₚ may be less than 1 µm but is preferably about 1 µm at minimum in view of production stability. Thus, the thickness Tₚ is preferably not less than 1 µm and not more than 500 µm.

A channel concentration in the channel layer 11b (a donor concentration in a region between two adjacent gate electrodes 13) and a mesa width Wₘ, which is a width of the mesa-shaped portion 18, are one of the parameters determining whether the trench-type MESFET 1 is of the normally-off type or the normally-on type, and the channel concentration and the mesa width Wₘ should be reduced to form the normally-off type, and the donor concentration and the mesa width Wₘ should be increased to form the normally-on type.

To suppress an off leakage current in the trench-type MESFET 1 when it is of the normally-off type, it is preferable that, e.g., the mesa width Wₘ be not more than 0.4 µm when a work function of the gate electrode 13 is 4.5 eV and the channel concentration in the channel layer 11b is from 5×10¹⁵ cm⁻³ to 1×10¹⁶ cm⁻³, the mesa width Wₘ be not more than 0.6 µm when the work function of the gate electrode 13 is 5.0 eV and the channel concentration in the channel layer 11b is not more than 5×10¹⁵ cm⁻³, the mesa width Wₘ be not more than 0.4 µm when the work function of the gate electrode 13 is 5.0 eV and the channel concentration in the channel layer 11b is more than 5×10¹⁵ cm⁻³ and not more than 1×10¹⁶ cm⁻³, and the mesa width Wₘ be not more than 0.6 µm when the work function of the gate electrode 13 is from 5.5 to 6.5 eV and the channel concentration in the channel layer 11b is from 5×10¹⁵ cm⁻³ to 1×10¹⁶ cm⁻³.

When the width Wₘ of the mesa-shaped regions is smaller, the channel concentration can be higher and on-resistance of the channel layer 11b can be thus reduced. However, when the width Wₘ is smaller, there is a problem that it is more difficult to manufacture and this causes a decrease in production yield.

For this reason, when the trenches 12 are formed by, e.g., patterning using a general stepper, the width Wₘ of the mesa-shaped regions is preferably not less than 0.5 µm and not more than 2 µm, and when the trenches 12 are formed by patterning using EB (electron beam) lithography with higher resolution, the width Wₘ of the mesa-shaped regions is preferably not less than 0.1 µm and not more than 2 µm.

A width Wt of the trench 12 also depends on the resolution of an exposure system and is thus preferably set within a numerical range similar to the width Wₘ of the mesa-shaped regions according to the type of the exposure system to be used.

A thickness of the contact layer 11c is, e.g., not less than 10 nm and not more than 5 µm. A donor concentration in the contact layer 11c is higher than the channel concentration in the channel layer 11b and is, e.g., not less than 1×10¹⁸ cm⁻³ and not more than 1×10²¹ cm⁻³.

The gate electrode 13 is formed of a material with which the channels in the mesa-shaped portions 18 can be opened/closed by applying a gate voltage within the range not causing gate leakage. When, e.g., NiO is used as a material of the gate electrode 13, applying a gate voltage within the range not causing gate leakage allows a wide range of current to flow from the drain electrode 17 to the source electrode 16 in the normally-off trench-type MESFET 1.

The insulators 14 are buried in the bottom portions of the trenches 12 and are located between the gate electrodes 13 and the withstand voltage layer 11a. Insulators 15 are buried in the trenches 12 so as to be placed on the gate electrodes 13 and are located between the gate electrodes 13 and the source electrode 16. The insulators 14 and the insulators 15 are formed of, e.g., HfO₂ or SiO₂.

The n-type semiconductor layer 11 is formed of, e.g., an epitaxially grown film formed by the HVPE method, etc. When the n-type semiconductor layer 11 is formed by the HVPE method, a chloride gas is used as a source material for Ga₂O₃-based single crystal or a dopant source material. Therefore, the n-type semiconductor layer 11 contains Cl derived from the source material for Ga₂O₃-based single crystal or the dopant source material.

When using the HVPE method, it is possible to reduce film formation time and the cost since the crystal growth rate is high. This feature is advantageous particularly when forming a thick n-type semiconductor layer 11. In addition, when using the HVPE method, it is possible to form the n-type semiconductor layer 11 with good crystal quality and thus possible to improve the production yield. Furthermore, since it is possible to form the n-type semiconductor layer 11 with high purity, it is possible to highly accurately control the donor concentration.

The contact layer 11c may be formed by implanting a donor, using an ion implantation process, into an upper portion of the channel layer 11b formed by epitaxial growth, but the manufacturing cost can be kept low when the Ga₂O₃-based single crystal is formed by crystal growth while adding a donor impurity.

The source electrode 16 is formed on the upper surface 19 of the n-type semiconductor layer 11 and is connected to the mesa-shaped portions 18. The drain electrode 17 is connected to a surface of the n-type semiconductor substrate 10 on the opposite side to the n-type semiconductor layer 11 as shown in FIG. 1, but may be connected to a surface of the n-type semiconductor layer 11 on the opposite side to the source electrode 16 when the trench-type MESFET 1 does not include the n-type semiconductor substrate 10. The drain electrode 17 is directly or indirectly connected with the opposite side to the source electrode 16 of the n-type semiconductor layer 11.

The source electrode 16 and the drain electrode 17 are respectively ohmic-connected to the contact layer 11c of the n-type semiconductor layer 11 and to the n-type semiconductor substrate 10. The source electrode 16 and the drain electrode 17 have, e.g., a Ti/Au stacked structure.

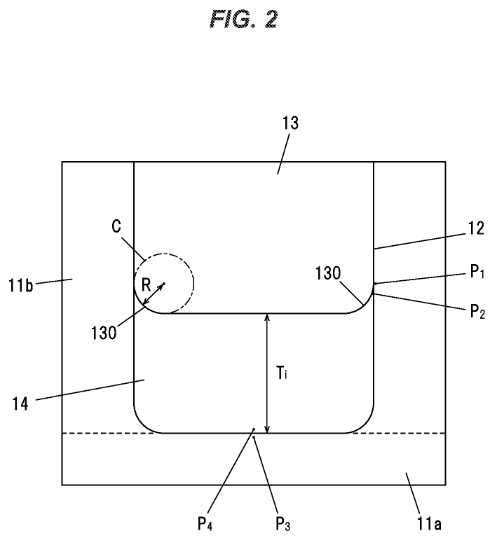

FIG. 2 is a partially enlarged view of FIG. 1, showing the vicinity of the bottom portion of the trench 12 of the trench-type MESFET 1.

Electric field intensity at a point P₁ in the channel layer 11b in the vicinity of an edge 130 (an end in a direction of the width Wt) of a bottom portion of the gate electrode 13 and electric field intensity at a point P₂ on an edge (an end in the direction of the width Wt) of an upper portion of the insulator 14 depend on a curvature radius R at an apex of a curve at the edge 130 of the bottom portion of the gate electrode 13 in a cross section in a width direction of the trench 12 (the direction of the width Wₜ) shown in FIG. 2.

When the vicinity of the apex of the curve at the edge 130 of the bottom portion of the gate electrode 13 in the cross section in the width direction of the trench 12 is approximated to a circular arc, a circle C shown in FIG. 2 is a circle including the circular arc and a radius of the circle C corresponds to the curvature radius R.

By keeping electric field intensity low at the point P₁ in the channel layer 11b and at the point P₂ in the insulator 14 which are at the end portion of the gate electrode 13, it is possible to suppress gate leakage over a Schottky barrier formed at an interface between the channel layer 11b and the gate electrode 13.

To prevent gate leakage in, e.g., the normally-off trench-type MESFET 1 at the time of applying a voltage of 1200 V between the source electrode 16 and the drain electrode 17, a value of the curvature radius R is preferably not less than 0.1 µm.

Meanwhile, electric field intensity at a point P₃ in the withstand voltage layer 11a in the vicinity of the center of the bottom portion of the trench 12 in the direction of the width Wt and electric field intensity at a point P₄ in the insulator 14 in the vicinity of the center of the bottom portion of the trench 12 in the direction of the width Wt depend on the donor concentration in the withstand voltage layer 11a and a thickness Tᵢ of the insulator 14.

By keeping electric field intensity low at the point P₃ in the withstand voltage layer 11a and at the point P₄ in the insulator 14 which are points with particularly high electric field intensity in the n-type semiconductor layer 11 and the insulator 14, it is possible to suppress dielectric breakdown of the n-type semiconductor layer 11 and the insulator 14.

To prevent dielectric breakdown of the n-type semiconductor layer 11 and the insulator 14 in, e.g., the normally-off trench-type MESFET 1 at the time of applying a voltage of 1200 V between the source electrode 16 and the drain electrode 17, the donor concentration in the withstand voltage layer 11a is preferably not more than 7×10¹⁶ cm⁻³ and the thickness Tᵢ of the insulator 14 is preferably in a range of not less than 50 nm and not more than 300 nm.

The insulators 14 and the insulators 15 are formed by, e.g., the atomic layer deposition (ALD) method. It is possible to control the shape of the edge of the upper portion of the insulator 14 by the formation conditions, etc., of the insulator 14, and thereby possible to control the curvature radius R of the gate electrode 13.

### Effects of the Embodiment

In the trench-type MESFET 1 in the above embodiment, high withstand voltage can be achieved by the trench structure and high-frequency driving can be achieved by the MESFET structure.

### Example 1

Current-voltage characteristics of the trench-type MESFET 1 in the embodiment described above were investigated by simulation. In this simulation, the electron affinity of the n-type semiconductor layer 11 was set to 3.7 eV assuming that the material thereof is Ga₂O₃, and the potential of the source electrode 16 was set to 0 V.

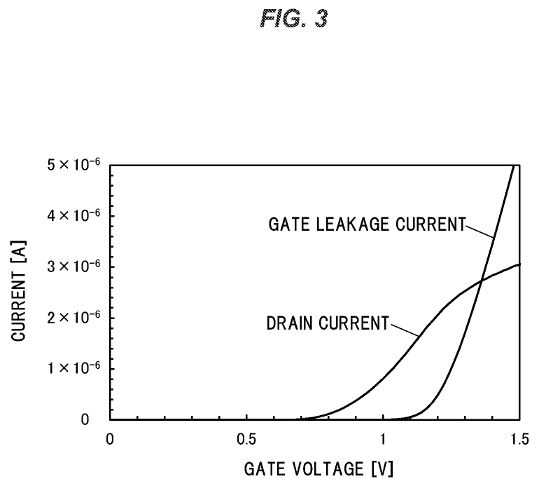

FIG. 3 is a graph showing a relationship between gate voltage and gate leakage current and a relationship between gate voltage and drain current for the trench-type MESFET 1 when the work function of the gate electrode 13 is set to 5.0 eV assuming that the material thereof is Pt and drain voltage of 20 V is applied.

According to FIG. 3, gate leakage occurs from around when the gate voltage goes beyond 1 V. In addition, by applying a gate voltage of 0 to 1 V at which gate leakage does not occur, a drain current of about 0 to 0.8×10⁻⁶ A flows. In addition, the threshold voltage (gate voltage at which the drain current starts to flow) is about 0.7 V.

As a result of research to find a more suitable material as the material of the gate electrode 13, the inventor found that NiO is suitable as the material of the gate electrode 13.

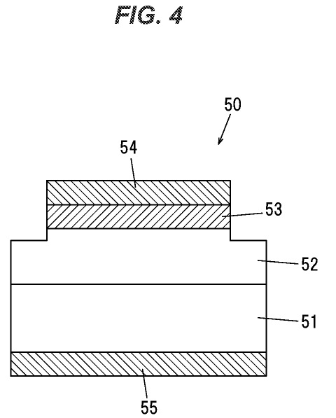

FIG. 4 is a vertical cross-sectional view showing a pn junction diode 50 having a p-type NiO film as a p-layer, which was used in the above-mentioned research. The pn junction diode 50 includes an n-type Ga₂O₃ substrate 51, an n-type Ga₂O₃ film 52 formed on the n-type Ga₂O₃ substrate 51, a p-type NiO film 53 formed on the n-type Ga₂O₃ film 52, an anode electrode 54 formed on the p-type NiO film 53, and a cathode electrode 55 formed on a surface of the n-type Ga₂O₃ substrate 51 on the opposite side to the n-type Ga₂O₃ film 52.

The n-type Ga₂O₃ film 52 and the p-type NiO film 53 form a pn junction, and the pn junction diode 50 uses rectifying characteristics of this pn junction.

In the pn junction diode 50, a potential barrier at an interface between the p-type NiO film 53 and the n-type Ga₂O₃ film 52 as viewed from the n-type Ga₂O₃ film 52 is lowered by applying forward voltage between the anode electrode 54 and the cathode electrode 55 (positive potential on the anode electrode 54 side), allowing a current to flow from the anode electrode 54 to the cathode electrode 55.

The n-type Ga₂O₃ substrate 51 is formed of an n-type Ga₂O₃ single crystal containing Sn as a donor impurity. A donor concentration in the n-type Ga₂O₃ substrate 51 is about 1.0×10¹⁸ cm⁻³. A thickness of the n-type Ga₂O₃ substrate 51 is about 600 µm.

The n-type Ga₂O₃ film 52 is formed of an n-type Ga₂O₃ single crystal containing Si as a donor impurity. A donor concentration in the n-type Ga₂O₃ film 52 is 6×10¹⁶ cm⁻³. A thickness of the n-type Ga₂O₃ film 52 is about 3 µm.

The p-type NiO film 53 is formed of p-type NiO.

The anode electrode 54 is composed of a circular Ni film with a diameter of 300 µm and forms an ohmic junction with the p-type NiO film 53.

The cathode electrode 55 is composed of a Ti/Au film and forms an ohmic junction with the n-type Ga₂O₃ substrate 51.

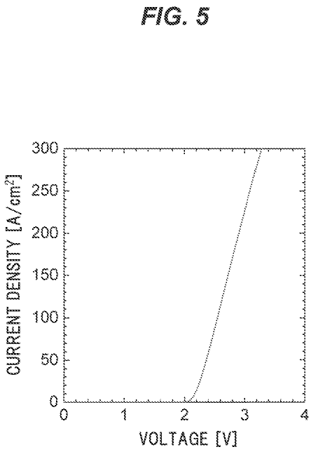

FIG. 5 is a graph showing a relationship between applied voltage and current density for the pn junction diode 50. From the characteristics of the pn junction diode 50 shown in FIG. 5, it was estimated that a Schottky barrier of about 2 eV is formed when NiO is used as the material of the gate electrode 13 of the trench-type MESFET 1, and based on this, the work function of NiO was estimated to be 5.7 eV.

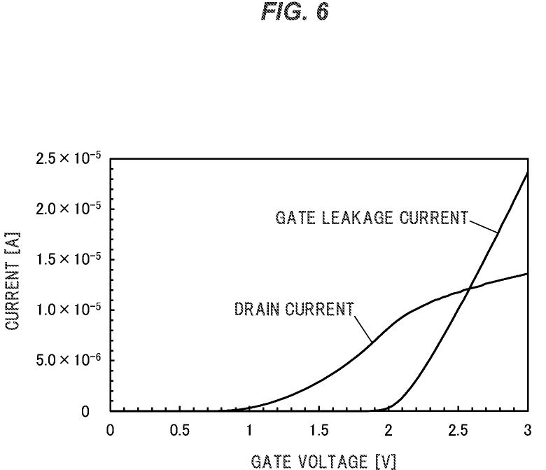

FIG. 6 is a graph showing a relationship between gate voltage and gate leakage current and a relationship between gate voltage and drain current for the trench-type MESFET 1 when NiO is used as the material of the gate electrode 13 and drain voltage of 20 V is applied.

According to FIG. 6, gate leakage does not occur even when applying a gate voltage of up to about 1.9 V. By applying a gate voltage of 0 to 1.9 V at which gate leakage does not occur, a drain current of about 0 to 7×10⁻⁶ A flows. The threshold voltage is about 0.9 V.

From the upper limit of the gate voltage which can be applied to the gate electrode 13 while suppressing occurrence of gate leakage and the range of drain current which can be passed while suppressing occurrence of gate leakage, it was confirmed that NiO is a more preferable material for the gate electrode 13 than Pt.

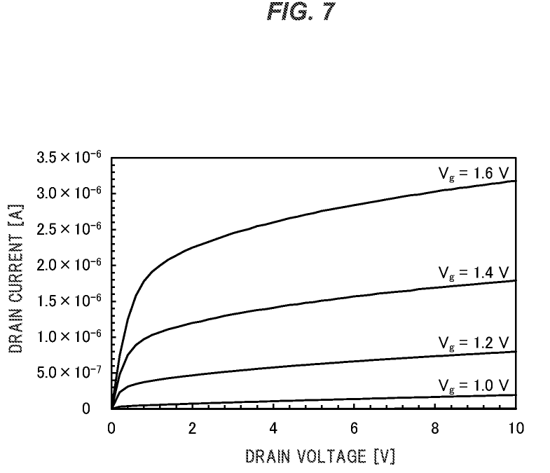

FIG. 7 is a graph showing a relationship between drain voltage and drain current for the trench-type MESFET 1 when the work function of the gate electrode 13 is set to 5.7 eV assuming that the material thereof is NiO and gate voltage of 0 to 1.6 V is applied. According to FIG. 7, perfect current-voltage characteristics are obtained.

Although the material (base crystal) of the n-type semiconductor layer 11 was a Ga₂O₃ single crystal in the simulation of Example 1, similar results are obtained also when simulating with other Ga₂O₃-based single crystals.

### Example 2

For the trench-type MESFET 1 in the embodiment described above, a relationship between the curvature radius R at the apex of the curve at the edge 130 of the bottom portion of the gate electrode 13 in the cross section in the width direction of the trench 12 and electric field intensity at the point P₁ in the channel layer 11b and at the point P₂ in the insulator 14 (see FIG. 2) was investigated by simulation.

In this simulation, the electron affinity of the n-type semiconductor layer 11 was set to 3.7 eV, the thickness Tₚ of the withstand voltage layer 11a was set to 4.3 µm, the width Wₘ of the mesa-shaped portion 18 was set to 0.4 µm, the channel concentration in the channel layer 11b was set to 1×10¹⁶ cm⁻³, the donor concentration in the withstand voltage layer 11a was set to 9×10¹⁶ cm⁻³, a dielectric constant of the insulator 14 was set to 22, the thickness Tᵢ of the insulator 14 was set to 0.2 µm, the work function of the gate electrode 13 was set to 5.0 eV, the potentials of the source electrode 16 and the gate electrode 13 were set to 0 V, and the potential of the drain electrode 17 was set to 1200 V. In this regard, the electron affinity of 3.7 eV for the n-type semiconductor layer 11 is based on the assumption that the material thereof is Ga₂O₃, the work function of 5.0 eV for gate electrode 13 is based on the assumption that the material thereof is Pt, and the dielectric constant of 22 for the insulator 14 is based on the assumption that the material thereof is HfO₂.

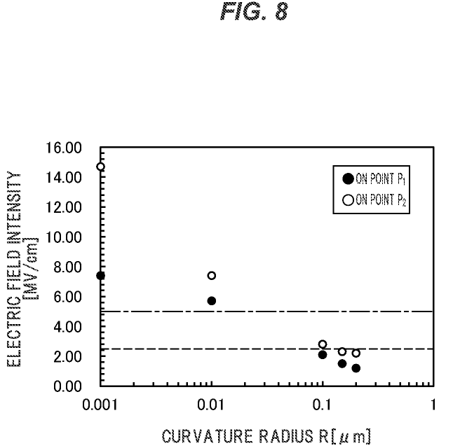

FIG. 8 is a graph showing a relationship between the curvature radius R and electric field intensity at the point P₁ in the channel layer 11b and at the point P₂ in the insulator 14. Numerical values of the points plotted in FIG. 8 are shown in Table 1 below.

Table 1

| Curvature radius R [µm] | Electric field intensity on Point P₁ [MV/cm] | Electric field intensity on Point P₂ [MV/cm] |
|---|---|---|
| 0.001 | 7.4 | 14.7 |
| 0.01 | 5.7 | 7.4 |
| 0.1 | 2.1 | 2.8 |
| 0.15 | 1.5 | 2.3 |
| 0.2 | 1.2 | 2.2 |

To suppress the gate leakage over the Schottky barrier formed at the interface between the channel layer 11b and the gate electrode 13, electric field intensity at the point P₁ in the channel layer 11b is preferably not more than 2.5 MV/cm (a dashed line in FIG. 8), and electric field intensity at the point P₂ in the insulator 14 is preferably not more than 5 MV/cm (a dash-dot line in FIG. 8).

According to FIG. 8, the range of the curvature radius R satisfying these conditions is not less than about 0.1 µm. Thus, to prevent gate leakage in the normally-off trench-type MESFET 1 at the time of applying a voltage of 1200 V between the source electrode 16 and the drain electrode 17, the curvature radius R of the gate electrode 13 is preferably not less than 0.1 µm.

Although the material (base crystal) of the n-type semiconductor layer 11 was a Ga₂O₃ single crystal in the simulation of Example 2, similar results are obtained also when simulating with other Ga₂O₃-based single crystals. In addition, although the material of the insulator 14 was HfO₂, similar results are obtained also when simulating with SiO₂.

### Example 3

For the trench-type MESFET 1 in the embodiment described above, a relationship between the donor concentration in the withstand voltage layer 11a and electric field intensity at the point P₃ in the withstand voltage layer 11a and at the point P₄ in the insulator 14 was investigated by simulation.

In this simulation, the electron affinity of the n-type semiconductor layer 11 was set to 3.7 eV, the thickness Tₚ of the withstand voltage layer 11a was set to 7 µm, the width Wₘ of the mesa-shaped portion 18 was set to 0.4 µm, the channel concentration in the channel layer 11b was set to 1×10¹⁶ cm⁻³, the dielectric constant of the insulator 14 was set to 22, the thickness Tᵢ of the insulator 14 was set to 0.2 µm, the work function of the gate electrode 13 was set to 5.0 eV, the curvature radius R of the gate electrode 13 was set to 0.2 µm, the potentials of the source electrode 16 and the gate electrode 13 were set to 0 V, and the potential of the drain electrode 17 was set to 1200 V. In this regard, the electron affinity of 3.7 eV for the n-type semiconductor layer 11 is based on the assumption that the material thereof is Ga₂O₃, the work function of 5.0 eV for gate electrode 13 is based on the assumption that the material thereof is Pt, and the dielectric constant of 22 for the insulator 14 is based on the assumption that the material thereof is HfO₂.

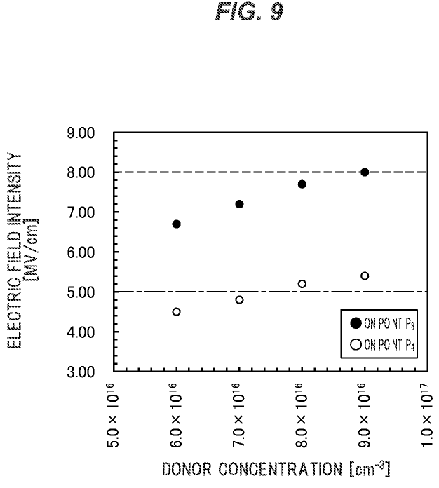

FIG. 9 is a graph showing a relationship between the donor concentration in the withstand voltage layer 11a and electric field intensity at the point P₃ in the withstand voltage layer 11a and at the point P₄ in the insulator 14. Numerical values of the points plotted in FIG. 9 are shown in Table 2 below.

Table 2

| Donor concentration [cm⁻³] | Electric field intensity on Point P₃ [MV/cm] | Electric field intensity on Point P₄ [MV/cm] |
|---|---|---|
| 6.0×10¹⁶ | 6.7 | 4.5 |
| 7.0×10¹⁶ | 7.2 | 4.8 |
| 8.0×10¹⁶ | 7.7 | 5.2 |
| 9.0×10¹⁶ | 8 | 5.4 |

To suppress dielectric breakdown of the n-type semiconductor layer 11 and the insulator 14, electric field intensity at the point P₃ in the withstand voltage layer 11a is preferably not more than 8 MV/cm (a dashed line in FIG. 9), and electric field intensity at the point P₄ in the insulator 14 is preferably not more than 5 MV/cm (a dash-dot line in FIG. 9).

According to FIG. 9, the range of the donor concentration in the withstand voltage layer 11a satisfying these conditions is not more than about 7.0×10¹⁶ cm⁻³. Thus, to prevent dielectric breakdown of the n-type semiconductor layer 11 and the insulator 14 in the normally-off trench-type MESFET 1 at the time of applying a voltage of 1200 V between the source electrode 16 and the drain electrode 17, the donor concentration in the withstand voltage layer 11a is preferably not more than 7×10¹⁶ cm⁻³.

Although the material (base crystal) of the n-type semiconductor layer 11 was a Ga₂O₃ single crystal in the simulation of Example 3, similar results are obtained also when simulating with other Ga₂O₃-based single crystals. In addition, although the material of the insulator 14 was HfO₂, similar results are obtained also when simulating with SiO₂.

### Example 4

For the trench-type MESFET 1 in the embodiment described above, a relationship between the thickness Tᵢ of the insulator 14 and electric field intensity at the point P₃ in the withstand voltage layer 11a and at the point P₄ in the insulator 14 was investigated by simulation.

In this simulation, the electron affinity of the n-type semiconductor layer 11 was set to 3.7 eV, the thickness Tₚ of the withstand voltage layer 11a was set to 4.4 µm, the width Wₘ of the mesa-shaped portion 18 was set to 0.4 µm, the channel concentration in the channel layer 11b was set to 1×10¹⁶ cm⁻³, the dielectric constant of the insulator 14 was set to 22, the work function of the gate electrode 13 was set to 5.0 eV, the curvature radius R of the gate electrode 13 was set to 0.2 µm, the potentials of the source electrode 16 and the gate electrode 13 were set to 0 V, and the potential of the drain electrode 17 was set to 1200 V. In this regard, the electron affinity of 3.7 eV for the n-type semiconductor layer 11 is based on the assumption that the material thereof is Ga₂O₃, the work function of 5.0 eV for gate electrode 13 is based on the assumption that the material thereof is Pt, and the dielectric constant of 22 for the insulator 14 is based on the assumption that the material thereof is HfO₂.

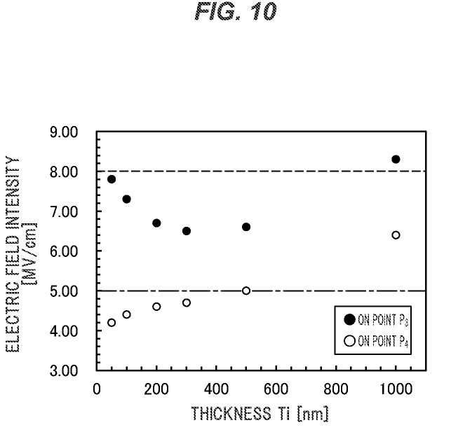

FIG. 10 is a showing a relationship between the thickness Tᵢ of the insulator 14 and electric field intensity at the point P₃ in the withstand voltage layer 11a and at the point P₄ in the insulator 14. Numerical values of the points plotted in FIG. 10 are shown in Table 3 below.

Table 3

| Thickness Tᵢ [nm] | Electric field intensity on Point P₃ [MV/cm] | Electric field intensity on Point P₄ [MV/cm] |
|---|---|---|
| 50 | 7.8 | 4.2 |
| 100 | 7.3 | 4.4 |
| 200 | 6.7 | 4.6 |
| 300 | 6.5 | 4.7 |
| 500 | 6.6 | 5 |
| 1000 | 8.3 | 6.4 |

As described above, to suppress dielectric breakdown of the n-type semiconductor layer 11 and the insulator 14, electric field intensity at the point P₃ in the withstand voltage layer 11a is preferably not more than 8 MV/cm (a dashed line in FIG. 10), and electric field intensity at the point P₄ in the insulator 14 is preferably not more than 5 MV/cm (a dash-dot line in FIG. 10).

According to FIG. 10, the range of the thickness Tᵢ of the insulator 14 satisfying these conditions is about not less than 50 nm and not more than 300 nm. Thus, to prevent dielectric breakdown of the n-type semiconductor layer 11 and the insulator 14 in the normally-off trench-type MESFET 1 at the time of applying a voltage of 1200 V between the source electrode 16 and the drain electrode 17, the thickness Tᵢ of the insulator 14 is preferably in the range of not less than 50 nm and not more than 300 nm.

Although the material (base crystal) of the n-type semiconductor layer 11 was a Ga₂O₃ single crystal in the simulation of Example 4, similar results are obtained also when simulating with other Ga₂O₃-based single crystals. In addition, although the material of the insulator 14 was HfO₂, similar results are obtained also when simulating with SiO₂.

Although the embodiments and Examples of the invention have been described, the invention is not intended to be limited to the embodiments and Examples, and the various kinds of modifications can be implemented without departing from the gist of the invention.

In addition, the invention according to claims is not to be limited to the embodiments and Examples described above. Further, it should be noted that not all combinations of the features described in the embodiments and Examples are necessary to solve the problem of the invention.

### Industrial Applicability

Provided is a trench-type MESFET that has a high withstand voltage and can be driven at high frequency.

### Reference Signs List

1 TRENCH-TYPE MESFET
10 N-TYPE SEMICONDUCTOR SUBSTRATE
11 N-TYPE SEMICONDUCTOR LAYER
11a WITHSTAND VOLTAGE LAYER
12 TRENCH
13 GATE ELECTRODE
14 INSULATOR
16 SOURCE ELECTRODE
17 DRAIN ELECTRODE
18 MESA-SHAPED PORTION
130 EDGE
R CURVATURE RADIUS
Tᵢ THICKNESS

1. A trench-type MESFET, comprising:
an n-type semiconductor layer comprising a Ga₂O₃-based single crystal and comprising a plurality of trenches opening on one surface;
first insulators respectively buried in bottom portions of the plurality of trenches;
gate electrodes respectively buried in the plurality of trenches so as to be placed on the first insulators and so that side surfaces thereof are in contact with the n-type semiconductor layer;
a source electrode connected to a mesa-shaped portion between the adjacent trenches of the n-type semiconductor layer;
second insulators respectively buried in the plurality of trenches so as to be placed on the gate electrodes to insulate the gate electrodes and the source electrode; and
a drain electrode directly or indirectly connected to the n-type semiconductor layer on a side opposite to the source electrode.

2. The trench-type MESFET according to claim 1, wherein the gate electrode comprises NiO.

3. The trench-type MESFET according to claim 1,wherein a curvature radius at an apex of a curve at an edge of a bottom portion of the gate electrode in a cross section in a width direction of the trench is not less than 0.1 µm.

4. The trench-type MESFET according to claim 1, wherein a donor concentration in a region of the n-type semiconductor layer between a bottom of the trench and a bottom surface of the n-type semiconductor layer is not more than 7x10¹⁶_{CM}-³.

5. The trench-type MESFET according to claim 1, wherein a thickness of the first insulator is in a range of not less than 50 nm and not more than 300 nm.
